(19) United States
(12) Patent Application Publication
(10) Pub. No.: US 2011/0061912 A1
(43) Pub. Date: Mar. 17, 2011

(54) Printed circuit board and manufacturing method thereof

(75) Inventors: Myung Sam Kang, Hwaseong (KR); Mi Sun Hwang, Suwon (KR); Ok Tae Kim, Suwon (KR); Seon Ha Kang, Cheongju (KR); Gil Yong Shin, Jeonju (KR); Kil Yong Yun, Suwon (KR); Min Jung Cho, Incheon (KR)

(73) Assignee: SAMSUNG ELECTRO-MECHANICS CO., LTD., Suwon (KR)

(21) Appl. No.: 12/654,668

(22) Filed: Dec. 29, 2009

(30) Foreign Application Priority Data
Sep. 14, 2009 (KR) 10-2009-0086605

(51) Int. Cl. H05K 1/00; H05K 1/11; B32B 38/10; B29C 65/00

(52) U.S. Cl. 174/258; 174/266; 156/247; 156/60

(57) ABSTRACT

Provided are a printed circuit board (PCB), and a manufacturing method thereof. The PCB includes a stacked structure including second and third insulation layers with a first insulation layer interposed therebetween, and a conductive via having first to fourth conductive vias. A second-layer circuit pattern and a third-layer circuit pattern are buried in the first insulation layer, a first-layer circuit pattern is formed on the second insulation layer, and a fourth-layer circuit pattern is formed on the third insulation layer. A first conductive via connects the first-layer circuit pattern and the second-layer circuit pattern, a second conductive via connects the first-layer circuit pattern and the third-layer circuit pattern, a third conductive via connects the second-layer circuit pattern and the fourth-layer circuit pattern, and a fourth conductive via connects the third-layer circuit pattern and the fourth-layer circuit pattern.

### CROSS-REFERENCE TO RELATED APPLICATIONS

This application claims the priority of Korean Patent Application No. 10-2009-0086605, filed on Sep. 14, 2009 in the Korean Intellectual Property Office, the disclosure of which is incorporated herein by reference.

### BACKGROUND OF THE INVENTION

1. Field of the Invention

The present invention relates to a printed circuit board and a manufacturing method thereof, and more particularly, to a slim printed circuit board having an interlayer connecting structure that is easily manufactured, and a method of manufacturing the same.

2. Description of the Related Art

In line with the downsizing, thinning, compacting and packaging trends of electronic appliances, a printed circuit board (PCB) also continues to be finely patterned, reduced in size and packaged. In order to form fine patterns and increase the reliability and design density of a PCB, a PCB structure must be changed to have a complex layered architecture together with a change in raw materials. A PCB component must also be changed from a dual in-line package (DIP) type to a surface mount technology (SMT) type, and thus a packaging density thereof increases as well.

In addition, demands for portability, high performance and multi-functionality such as Internet browsing, motion picture viewing, and high-capacity data transmission/reception in electronic appliances cause the design of a PCB to be complicated and require a highly complex manufacturing technique.

PCBs are classified into roughly three types, that is, a single sided PCB in which an interconnection is formed on only one side of an insulating board, a double sided PCB in which interconnections are formed on both sides of an insulating board, and a multilayer PCB (MLB) in which interconnections are formed in a multilayered configuration. In the past, a single sided PCB has been used because the components thereof were simple and circuit patterns were also simply formed. However, a double sided PCB or MLB is recently in use due to an increase in the complexity of circuits and demands for circuits having a higher density and a smaller size.

An MLB is designed to have a structure in which an additional layer where an interconnection is formed is provided, so as to enlarge an interconnection area. Specifically, an MLB employs a four-layer structure in which layers are divided into two inner layers and two outer layers, the inner layers are made of a thin core, and the inner layers and the outer layers are attached using a prepreg. The MLB may have a six-, eight-, or ten-layer structure according to the complexity of the circuits formed thereuopn.

A power supply circuit, a ground circuit, a signal circuit, etc., are formed on the inner layer, and insulating and attaching treatments are performed between the inner layer and the outer layer, and between the outer layers. Respective layers are interconnected using via holes.

Although an MLB is advantageous in that interconnection density is significantly increased, a manufacturing process thereof is overly complicated, and typical manufacturing methods may make it difficult to obtain a thin board having a four-layer structure because of difficulty in reducing the thickness of an inner layer board.

### SUMMARY OF THE INVENTION

An aspect of the present invention provides a multilayer printed circuit board (PCB) with a small thickness having an interlayer connecting structure that is easily manufactured, and a method of manufacturing the same.

According to an aspect of the present invention, there is provided a PCB including: a stacked structure including a first insulation layer in which a second-layer circuit pattern and a third-layer circuit pattern are buried, a second insulation layer on which a first-layer circuit pattern is formed, and a third insulation layer on which a fourth-layer circuit pattern is formed, the first insulation layer being interposed between the second and third insulation layers; and a conductive via electrically connecting the circuit patterns. Herein, the conductive via includes: a first conductive via connecting the first-layer circuit pattern and the second-layer circuit pattern; a second conductive via connecting the first-layer circuit pattern and the third-layer circuit pattern; a third conductive via connecting the second-layer circuit pattern and the fourth-layer circuit pattern, and a fourth conductive via connecting the third-layer circuit pattern and the fourth-layer circuit pattern.

The conductive via may include a stacked via including the first and third conductive vias, wherein the first-layer circuit pattern and the fourth-layer circuit pattern are connected to each other through the stacked via.

The conductive via may include a stacked via including the second and fourth conductive vias, wherein the first-layer circuit pattern and the fourth-layer circuit pattern are connected to each other through the stacked via.

The first insulation layer may be formed of a prepreg, and the second and third insulation layers may be formed of a dielectric layer constituting a copper clad laminate (CCL).

The first, second and third insulation layers may be formed of a prepreg.

According to another aspect of the present invention, there is provided a PCB including: a stacked structure including a first insulation layer on which a second-layer circuit pattern and a third-layer circuit pattern are formed, a second insulation layer on which a first-layer circuit pattern is formed, and a third insulation layer on which a fourth-layer circuit pattern is formed, the first insulation layer being interposed between the second and third insulation layers; and a conductive via electrically connecting the circuit patterns. Herein, the conductive via includes: a first conductive via connecting the first-layer circuit pattern and the second-layer circuit pattern; a second conductive via connecting the first-layer circuit pattern and the third-layer circuit pattern; a third conductive via connecting the second-layer circuit pattern and the fourth-layer circuit pattern, and a fourth conductive via connecting the third-layer circuit pattern and the fourth-layer circuit pattern.

The conductive via may include a stacked via including the first and third conductive vias, wherein the first-layer circuit pattern and the fourth-layer circuit pattern are connected to each other through the stacked via.

The conductive via may include a stacked via including the second and fourth conductive vias, wherein the first-layer circuit pattern and the fourth-layer circuit pattern are connected to each other through the stacked via.

According to still another aspect of the present invention, there is provided a method of manufacturing a PCB, including: stacking a first CCL including first and second copper foil layers and a second CCL including third and fourth copper foil layers on both sides of an adhesive layer; forming a second-layer circuit pattern and a third-layer circuit pattern on the second and third copper foil layers not contacting the adhesive layer, respectively; separating the first and second CCLs from the adhesive layer; burying the second-layer circuit pattern and the third-layer circuit pattern into a prepreg by pressing the first and second CCLs with the prepreg interposed therebetween; forming first, second, third and fourth conductive vias in the first and second CCLs and the prepreg, the first conductive via connecting a first-layer circuit pattern formed on the first copper foil layer and the second-layer circuit pattern, the second conductive via connecting the first-layer circuit pattern and the third-layer circuit pattern, the third conductive via connecting the second-layer circuit pattern and a fourth-layer circuit pattern formed on the fourth copper foil layer, and the fourth conductive via connecting the third-layer circuit pattern and the fourth-layer circuit pattern; and forming the first-layer circuit pattern and the fourth-layer circuit pattern on the first and fourth copper foil layers, respectively.

According to yet another aspect of the present invention, there is provided a method of manufacturing a PCB, including: attaching first and second metal foil layers on both sides of an adhesive layer; forming a second-layer circuit pattern and a third-layer circuit pattern on the first and second metal foil layers, respectively; separating the first and second metal foil layers from the adhesive layer; burying the second-layer circuit pattern and the third-layer circuit pattern into a first prepreg by pressing the first and second metal foil layers with the first prepreg interposed therebetween; stacking a second prepreg and a third metal foil layer on one side of the first prepreg, and a third prepreg and a fourth metal foil layer on the other side of the first prepreg; forming first, second, third and fourth conductive vias in the first, second and third prepregs, the first conductive via connecting a first-layer circuit pattern formed on the third metal foil layer and the second-layer circuit pattern, the second conductive via connecting the first-layer circuit pattern and the third-layer circuit pattern, the third conductive via connecting the second-layer circuit pattern and a fourth-layer circuit pattern formed on the fourth metal foil layer, and the fourth conductive via connecting the third-layer circuit pattern and the fourth-layer circuit pattern; and forming the first-layer circuit pattern and the fourth-layer circuit pattern on the third and fourth copper foil layers, respectively.

According to another aspect of the present invention, there is provided a method of manufacturing a PCB, including: preparing a CCL including first and second copper foil layers on both sides of a dielectric layer; forming a second-layer circuit pattern and a third-layer circuit pattern on the first and second metal foil layers, respectively; stacking a first prepreg and a first metal foil layer on one side of the dielectric layer, and a second prepreg and a second metal foil layer on the other side of the dielectric layer; forming first, second, third and fourth conductive vias in the first and second prepregs, the first conductive via connecting a first-layer circuit pattern formed on the first metal foil layer and the second-layer circuit pattern, the second conductive via connecting the first-layer circuit pattern and the third-layer circuit pattern, the third conductive via connecting the second-layer circuit pattern and a fourth-layer circuit pattern formed on the second metal foil layer, and the fourth conductive via connecting the third-layer circuit pattern and the fourth-layer circuit pattern; and forming the first-layer circuit pattern and the fourth-layer circuit pattern on the first and second metal foil layers, respectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating a printed circuit board (PCB) according to an embodiment of the present invention;

FIG. 2 is a cross-sectional view schematically illustrating a PCB according to another embodiment of the present invention;

FIG. 3 is a cross-sectional view schematically illustrating a PCB according to still another embodiment of the present invention;

FIGS. 4A through 4G are cross-sectional views illustrating a method of manufacturing a PCB according to an embodiment of the present invention;

FIGS. 5A through 5H are cross-sectional views illustrating a method of manufacturing a PCB according to another embodiment of the present invention; and

FIGS. 6A through 6D are cross-sectional views illustrating a method of manufacturing a PCB according to still another embodiment of the present invention.

### DETAILED DESCRIPTION OF THE PREFERRED EMBODIMENT

Exemplary embodiments of the present invention will be described below with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus a detailed description thereof will be omitted.

The present invention will now be described in more detail with reference to the accompanying drawings.

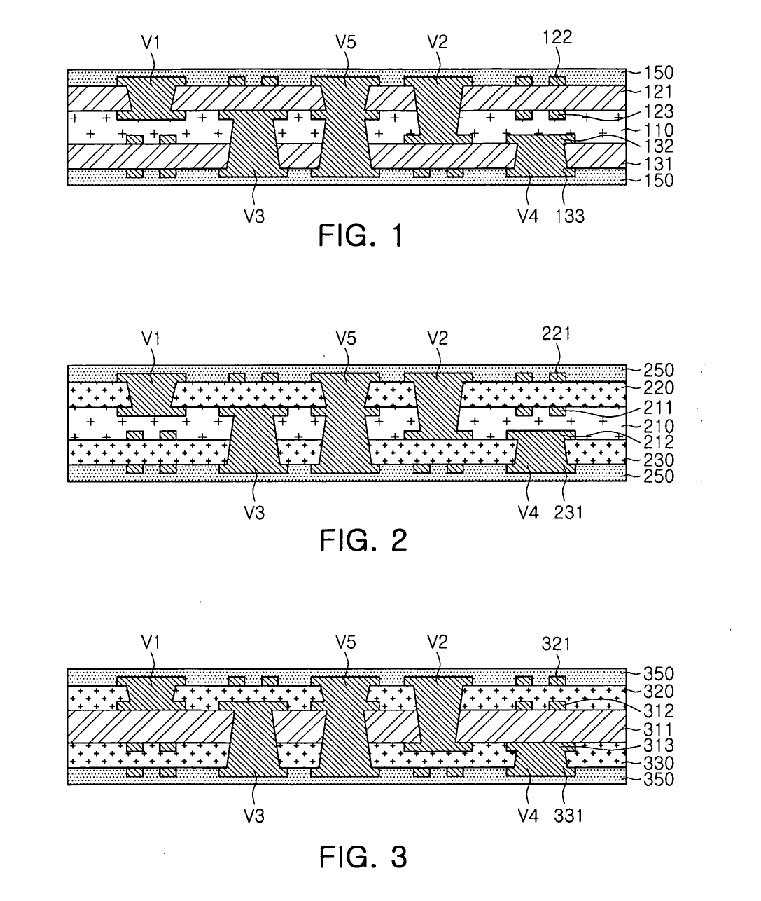

FIG. 1 is a cross-sectional view schematically illustrating a printed circuit board (PCB) according to an embodiment of the present invention. Referring to FIG. 1, in the PCB according to this exemplary embodiment, a stacked structure is formed, which includes a second insulation layer 121 and a third insulation layer 131 with a first insulation layer 110 interposed therebetween.

A second-layer circuit pattern 123 and a third-layer circuit pattern 132 are buried in the first insulation layer 110.

The first insulation layer 110 may be formed of a prepreg prepared by permeating a thermosetting resin into a glass fiber and semi-hardening the resultant.

A first-layer circuit pattern 122 is formed on the second insulation layer 121, and a fourth-layer circuit pattern 133 is formed on the third insulation layer 131.

The second and third insulation layers 121 and 131 may be formed of a dielectric layer forming a copper clad laminate.

The PCB according to this exemplary embodiment includes a conductive via for electrically connecting the circuit patterns of respective layers.

A first conductive via V1 connects the first-layer circuit pattern 122 and the second-layer circuit pattern 123, and a second conductive via V2 connects the first-layer circuit pattern 122 and the third-layer circuit pattern 132.

A third conductive via V3 connects the second-layer circuit pattern 123 and the fourth-layer circuit pattern 133, and a fourth conductive via V4 connects the third-layer circuit pattern 132 and the fourth-layer circuit pattern 133.

The first-layer circuit pattern 122 and the fourth-layer circuit pattern 133 may be electrically connected to each other through the first conductive via V1 and the third conductive via V3.

The conductive via may include a stack via V5 configured with the first and third conductive vias V1 and V3, and the first-layer circuit pattern 122 and the fourth-layer circuit pattern 133 may be electrically connected through the stack via V5.

Alternatively, The conductive via may include a stack via (not shown) configured with the second and fourth conductive vias V2 and V4, and the first-layer circuit pattern 122 and the fourth-layer circuit pattern 133 may be electrically connected through this stack via.

A solder resist layer 150 may be formed on the first-layer circuit pattern 122 and the fourth-layer circuit pattern 133.

FIG. 2 is a cross-sectional view schematically illustrating a PCB according to another embodiment of the present invention. A description will be given of elements differing from those of the PCB of FIG. 1, and thus a detailed description of the same elements will be omitted herein.

Referring to FIG. 2, in the PCB according to this exemplary embodiment, a stacked structure is formed, which includes a second insulation layer 220 and a third insulation layer 230 with a first insulation layer 210 interposed therebetween.

A second-layer circuit pattern 211 and a third-layer circuit pattern 212 are buried in the first insulation layer 210.

A first-layer circuit pattern 221 is formed on the second insulation layer 220, and a fourth-layer circuit pattern 231 is formed on the third insulation layer 230.

The first, second and third insulation layers 210, 220 and 230 may be formed of a prepreg prepared by permeating a thermosetting resin into a glass fiber and semi-hardening the resultant.

The PCB according to this exemplary embodiment includes conductive vias for electrically connecting the circuit patterns of respective layers, and particulars about the conductive vias are identical or similar to those of the previous exemplary embodiment.

Also, a solder resist layer 250 may be formed on the first-layer circuit pattern 221 and the fourth-layer circuit pattern 231.

FIG. 3 is a cross-sectional view schematically illustrating a PCB according to still another embodiment of the present invention. A description will be given of elements differing from those of the PCBs of FIGS. 1 and 2, and thus a detailed description of the same elements will be omitted herein.

Referring to FIG. 3, in the PCB according to this exemplary embodiment, a stacked structure is formed, which includes a second insulation layer 320 and a third insulation layer 330 with a first insulation layer 311 interposed therebetween.

A second-layer circuit pattern 312 and a third-layer circuit pattern 313 are formed on the first insulation layer 311.

A first-layer circuit pattern 321 is formed on the second insulation layer 320, and a fourth-layer circuit pattern 331 is formed on the third insulation layer 330.

The first to third insulation layers 311, 320 and 330 may be formed of a prepreg prepared by permeating a thermosetting resin into a glass fiber and semi-hardening the resultant.

The PCB according to this exemplary embodiment includes conductive vias for electrically connecting the circuit patterns disposed in different layers, and particulars regarding the conductive via are identical or similar to those of the previous exemplary embodiments.

Also, a solder resist layer 350 may be formed on the first-layer circuit pattern 321 and the fourth-layer circuit pattern 331.

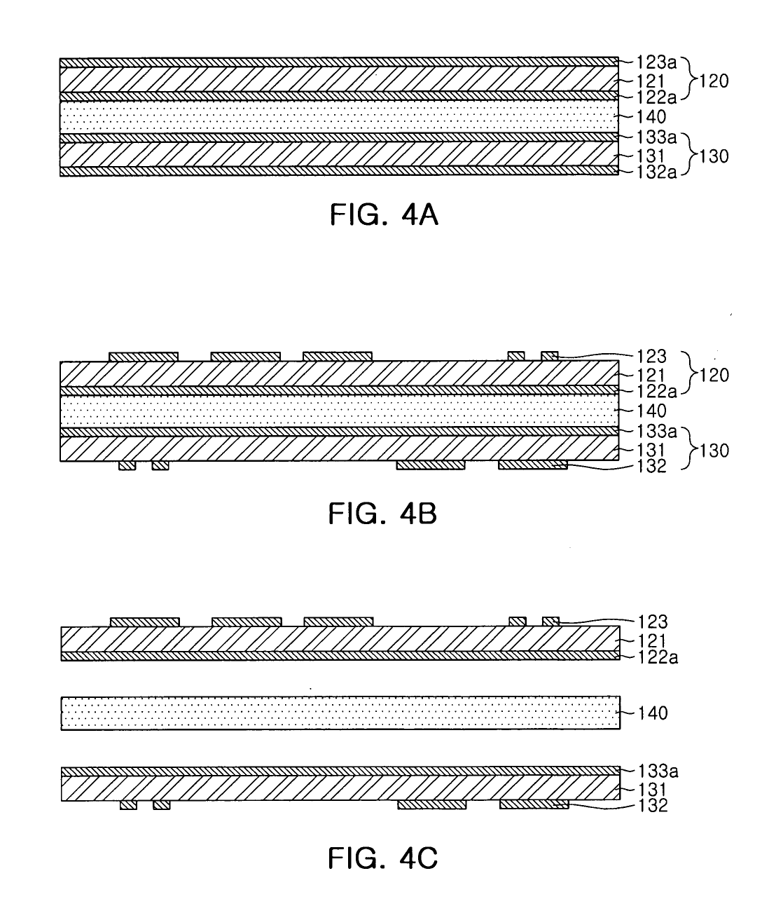

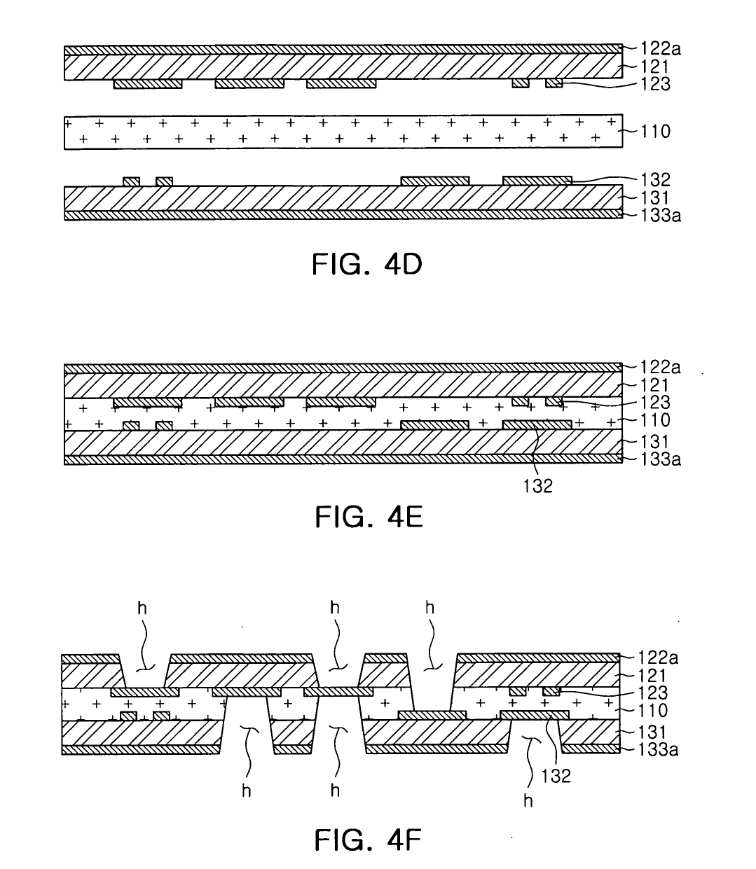

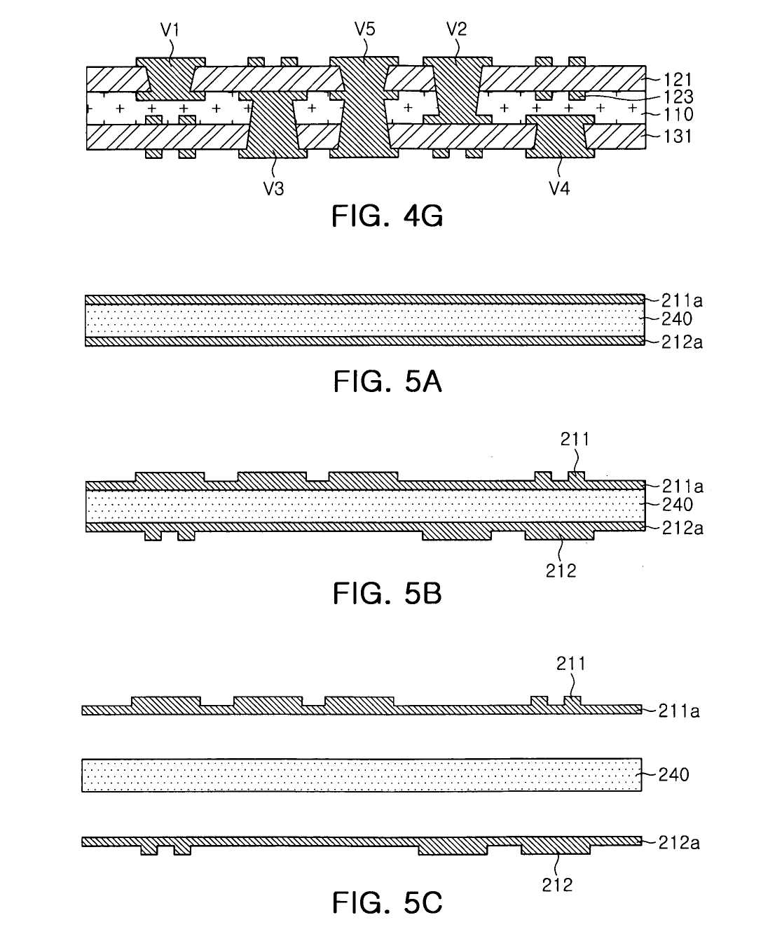

FIGS. 4A through 4G are cross-sectional views illustrating a method of manufacturing a PCB according to an embodiment of the present invention.

As illustrated in FIG. 4A, first and second copper clad laminates (CCLs) 120 and 130 are attached on both sides of an adhesive layer 140. During a subsequent process, the first CCL 120 forms first and second layers of the PCB, and the second CCL 130 forms third and fourth layers of the PCB.

In this case, the first and fourth layers, which correspond to outer-layer circuits of the PCB having a four-layer structure, are in contact with the adhesive layer 140, and the second and third layers corresponding to inner-layer circuits are exposed to the outside.

The first CCL 120 includes a dielectric layer 121 formed of a material having a high dielectric constant, and first and second copper foil layers 122a and 123a are formed on both sides of the dielectric layer 121. The first copper foil layer 122a contacts the adhesive layer 140 to form the first layer of the PCB, and the second copper foil layer 123a forms the second layer.

The second CCL 130 includes a dielectric layer 131 formed of a high dielectric constant material, and third and fourth copper foil layers 132a and 133a formed on both sides of the dielectric layer 131. The fourth copper foil layer 132a contacts the adhesive layer 140 to form the fourth layer of the PCB, and the third copper foil layer 133a forms the third layer.

It is difficult to utilize a device for forming circuits only with only one CCL due to the slimness of the dielectric layers 121 and 131, and therefore two CLLs 120 and 130 are attached to both sides of the adhesive layer 140 so as to secure a predetermined thickness for utilizing devices used in the manufacture of the PCB. The adhesive layer 140 can be easily removed through high-temperature/high-pressure process later.

Thereafter, as illustrated in FIG. 4B, circuit patterns 123 and 132 are formed in the second and third cooper foil layers 123a and 132a, respectively. That is, inner-layer circuit patterns are formed, which correspond to the second-layer circuit pattern 123 and the third-layer circuit pattern 132 of the PCB having the four-layer structure.

A method of forming circuit patterns is not specifically limited, and thus typical processes may be used in the present technical field. For example, circuit patterns may be formed by coating, exposing, developing, etching and delaminating a photoresist layer (dry film, LPR, or the like).

Afterwards, as illustrated in FIG. 4C, the first and second CCLs 120 and 130 are separated from the adhesive layer 140.

The adhesive force of the adhesive layer 140 may be susceptible to deterioration when it is exposed to ultraviolet light or heat. The first and second CCLs 120 and 130 are separated from the adhesive layer 140 by performing high-temperature/high-pressure process using a nitrogen oven.

Next, as illustrated in FIG. 4D, the first and second CCLs 120 and 130 are disposed such that the second-layer circuit pattern 123 formed on the first CCL 120 and the third-layer circuit pattern 132 formed on the second CCL 130 both face a prepreg 110.

That is, the first and second CCLs 120 and 130 are disposed such that the second-layer circuit pattern 123 and the third-layer circuit pattern 132 form the inner-layer circuit patterns of the PCB having the four-layer structure.

Subsequently, as illustrated in FIG. 4E, high pressure is exerted on the first and fourth copper foil layers 122a and 133a where circuit patterns are not formed, thus allowing the first and second CCLs 120 and 130 to be attached to the prepreg 110.

Since circuits are not yet formed in the first copper foil layer 122a of the first CCL 120 and the fourth copper foil layer 133a of the second CCL 130, they are not damaged even if high pressure is exerted thereupon, and the second-layer circuit pattern 123 and the third-layer circuit pattern 132 are resultantly buried in the prepreg 110. Thus, it is possible to prevent delamination by burying such circuit patterns.

After that, as illustrated in FIG. 4F, a via hole h is formed for interlayer connection of the PCB.

The via hole h may be formed using mechanical drilling or a laser, and examples of the laser may be a YAG layer or CO2 laser.

Thereafter, the via hole h is filled with a filler to thereby form a conductive via.

As illustrated in FIG. 4G, a fill-plating process may be performed to completely fill the via holes.

Alternatively, an inner wall of the via hole is plated, and thereafter an empty space of the via hole h is filled with a plugging ink, a conductive paste or a dielectric material.

The conductive vias are used to electrically connect circuit patterns of respective layers, and the PCB according to this exemplary embodiment employs four types of conductive vias.

The first conductive via V1 is formed to connect the first-layer circuit pattern 122 and the second-layer circuit pattern 123, and the second conductive via V2 is formed to connect the first-layer circuit pattern 122 and the third-layer circuit pattern 132.

Likewise, the third conductive via V3 is formed to connect the second-layer circuit pattern 123 and the fourth-layer circuit pattern 133, and the fourth conductive via V4 is formed to connect the third-layer circuit pattern 132 and the fourth-layer circuit pattern 133.

The first-layer circuit pattern 122 and the fourth-layer circuit pattern 133 may be electrically connected to each other by means of the first conductive via V1 and the third conductive via V3. To this end, the first conductive via V1 and the third conductive via V3 may be formed into a stack via V5.

Alternatively, the first-layer circuit pattern 122 and the fourth-layer circuit pattern 133 may be electrically connected to each other by means of the second conductive via V2 and the fourth conductive via V4. To this end, the second conductive via V2 and the fourth conductive via V4 may be formed into a stack via (not shown).

A method of forming circuit patterns is not specifically limited, and thus typical processes may be used in the present technical field. For example, circuit patterns may be formed by coating, exposing, developing, etching and delaminating a photoresist layer (dry film, LPR, or the like).

That is, without using a separate stacking process, it is possible to form an outer-layer circuit of the PCB having a four-layer structure using the first copper foil layer 122a of the first CCL 120 and the fourth copper foil layer 133a of the second CCL 130.

Afterwards, a solder resist layer (not shown) may be formed on the first-layer circuit pattern 122 and the fourth-layer circuit pattern 133.

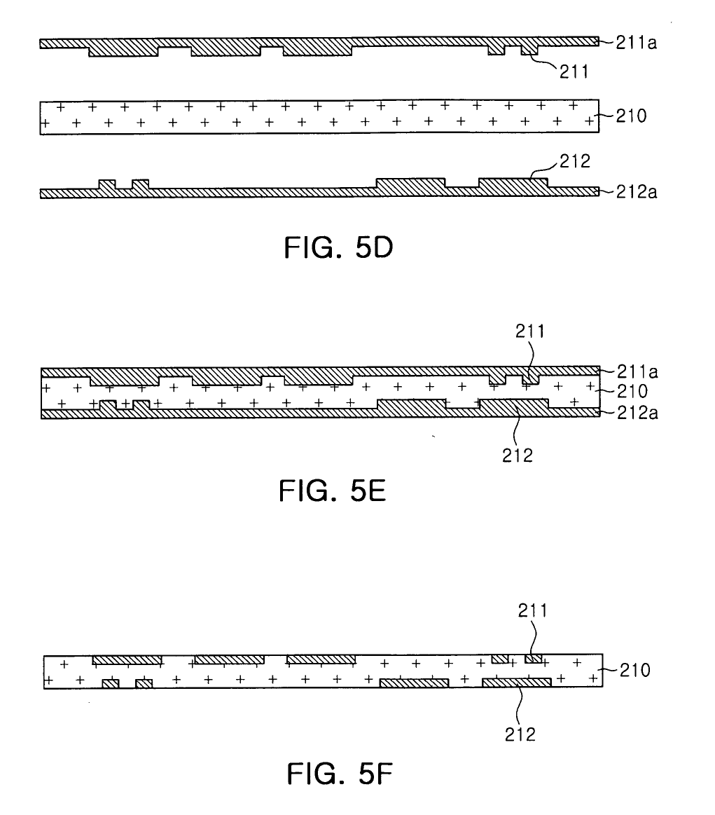

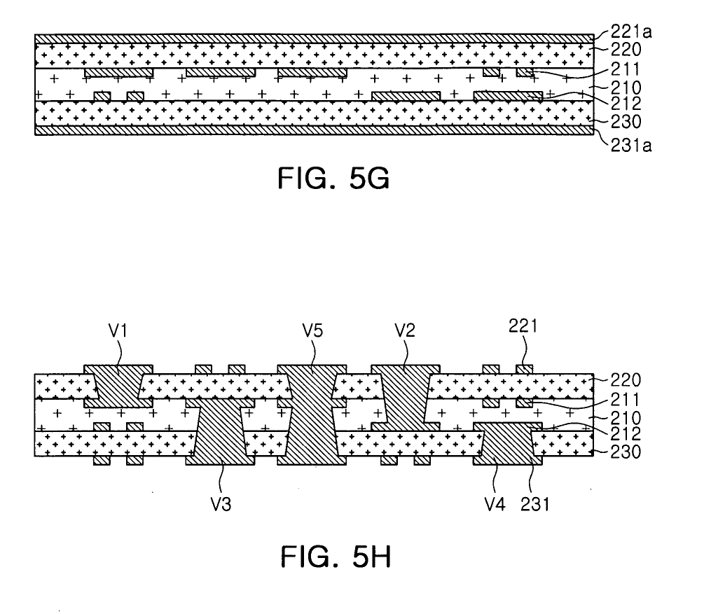

FIGS. 5A through 5H are cross-sectional views illustrating a method of manufacturing a PCB according to another embodiment of the present invention. A description will be given of elements differing from those of the foregoing exemplary embodiment, and thus a detailed description of the same elements will be omitted herein.

As illustrated in FIG. 5A, metal foil layers 211a and 212a are attached on both sides of an adhesive layer 240. Each of the metal foil layers 211a and 212a may have a monolayer or a multilayer, and may include copper (Cu). The metal foil layer may have a thickness of about 12 on or greater.

During a subsequent process, the first metal foil layer 211a forms a second-layer circuit pattern of the PCB, and the second metal foil layer 212a forms a third-layer circuit pattern of the PCB.

Thereafter, as illustrated in FIG. 5B, circuit patterns 211 and 212 are formed on the first and second metal foil layers 211a and 212a, respectively. That is, inner-layer circuit patterns are formed, which correspond to the second-layer circuit pattern 211 and the third-layer circuit pattern 212 of the PCB having the four-layer structure.

A method of forming circuit patterns is not specifically limited, and thus typical processes used in the present technical field may be adopted depending on the structure of the metal foil layer. For example, circuit patterns may be formed by coating, exposing, developing, etching and delaminating a photoresist layer. Also, circuit patterns may be formed by forming a seed layer through electroless plating and then performing coating process.

Afterwards, as illustrated in FIG. 5C, the first metal foil layer 211a with the second-layer circuit pattern 211 formed and the second metal foil layer 212a with the third-layer circuit pattern 212 formed are separated from the adhesive layer 240.

Next, as illustrated in FIG. 5D, the first and second metal foil layers 211a and 212a are disposed such that the second-layer circuit pattern 211 formed on the first metal foil layer 211a and the third-layer circuit pattern 212 formed on the second metal foil layer 212a face a first prepreg 210. That is, the first and second metal foil layers 211a and 212a are disposed such that the second-layer circuit pattern 211 and the third-layer circuit pattern 212 form inner-layer circuit patterns of the PCB having the four-layer structure. Here, the first prepreg 210 forms a first insulation layer of the PCB.

Subsequently, as illustrated in FIG. 5E, high pressure is exerted on the first and second metal foil layers 211a and 212a, thereby burying the second-layer circuit pattern 211 and the third-layer circuit pattern 212 into the first prepreg 210. Thus, it is possible to prevent delamination by burying such circuit patterns.

After that, as illustrated in FIG. 5F, the first and second metal foil layers 211a and 212a are removed. The removal of the metal foil layers 211a and 212a may be performed through chemical process such as etching.

Thereafter, as illustrated in FIG. 5G, a second prepreg 220 and a third metal foil layer 221a are stacked on one side of the first prepreg 210, and a third prepreg 230 and a fourth metal foil layer 231a are stacked on the other side of the first prepreg 210.

Afterwards, like the foregoing embodiment, a via hole is formed for interlayer connection of the PCB, and the via hole is filled with a filler to form a conductive via.

Like the foregoing embodiment, a first conductive via V1 may be formed to connect the first-layer circuit pattern and the second-layer circuit pattern, and a second conductive via V2 may be formed to connect the first-layer circuit pattern and the third-layer circuit pattern. A third conductive via V3 may be formed to connect the second-layer circuit pattern and the fourth-layer circuit pattern, and a fourth conductive via V4 may be formed to connect the third-layer circuit pattern and the fourth-layer circuit pattern. The first conductive via V1 and the third conductive via V3 may be formed into a stack via V5.

Next, as illustrated in FIG. 5H, circuit patterns 221 and 231 are formed in the third and fourth metal foil layers 221a and 231a, respectively. That is, outer-layer circuit patterns are formed, which correspond to the first-layer circuit pattern 211 and the fourth-layer circuit pattern 231 of the PCB having the four-layer structure.

After that, a solder resist layer (not shown) may be formed on the first-layer circuit pattern 221 and the fourth-layer circuit pattern 231.

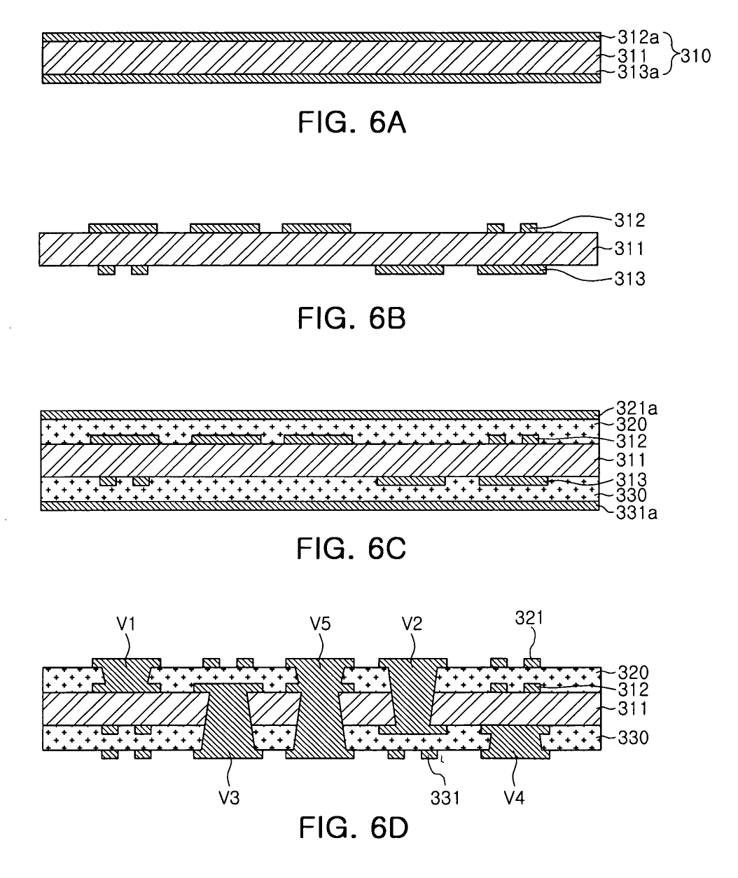

FIGS. 6A through 6D are cross-sectional views illustrating a method of manufacturing a PCB according to another embodiment of the present invention. A description will be given of elements differing from those of the foregoing exemplary embodiments, and thus detailed description for the same elements will be omitted herein.

A CCL 310 is prepared, as illustrated in FIG. 6A. The CCL 310 includes a dielectric layer 311 formed of a material having a high dielectric constant, and first and second copper foil layers 312a and 313a are formed on both sides of the dielectric layer 311. During a subsequent process, the first copper foil layer 312a forms a second-layer circuit pattern of the PCB, and the second metal foil layer 313a forms a third-layer circuit pattern of the PCB.

Thereafter, as illustrated in FIG. 6B, circuit patterns 312 and 313 are formed on the first and second copper foil layers 312a and 313a, respectively. That is, inner-layer circuit patterns are formed, which correspond to the second-layer circuit pattern 312 and the third-layer circuit pattern 313 of the PCB having the four-layer structure.

Afterwards, as illustrated in FIG. 6C, a first prepreg 320 and a first metal foil layer 321a are stacked on one side of the dielectric layer 311 of the CCL 310 with the first-layer circuit pattern 312 formed, and a second prepreg 330 and a second metal foil layer 331a are stacked on the other side of the dielectric layer 311 of the CCL 310 with the second-layer circuit pattern 313 formed.

Afterwards, like the foregoing embodiment, a via hole is formed for interlayer connection of the PCB, the via hole is then filled with a filler to form a conductive via.

Like the foregoing embodiment, a first conductive via V1 may be formed to connect the first-layer circuit pattern and the second-layer circuit pattern, and a second conductive via V2 may be formed to connect the first-layer circuit pattern and the third-layer circuit pattern. A third conductive via V3 may be formed to connect the second-layer circuit pattern and the fourth-layer circuit pattern, and a fourth conductive via V4 may be formed to connect the third-layer circuit pattern and the fourth-layer circuit pattern. The first conductive via V1 and the third conductive via V3 may be formed into a stack via V5.

Next, as illustrated in FIG. 6D, circuit patterns 321 and 331 are formed in the first and second metal foil layers 321a and 331a, respectively. That is, outer-layer circuit patterns are formed, which correspond to the first-layer circuit pattern 321 and the fourth-layer circuit pattern 331 of the PCB having the four-layer structure.

After that, a solder resist layer (not shown) may be formed on the first-layer circuit pattern 321 and the fourth-layer circuit pattern 331.

According to a method of manufacturing a PCB, it is possible to form a high-density circuit pattern using typical apparatuses.

Also, the PCB according to the present invention includes an interlayer connecting structure that is easily manufactured, and has a four-layer structure with a small thickness.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board (PCB) comprising:
a stacked structure including a first insulation layer in which a second-layer circuit pattern and a third-layer circuit pattern are buried, a second insulation layer on which a first-layer circuit pattern is formed, and a third insulation layer on which a fourth-layer circuit pattern is formed, the first insulation layer being interposed between the second and third insulation layers; and
a conductive via electrically connecting the circuit patterns,
wherein the conductive via comprises:
a first conductive via connecting the first-layer circuit pattern and the second-layer circuit pattern;
a second conductive via connecting the first-layer circuit pattern and the third-layer circuit pattern;
a third conductive via connecting the second-layer circuit pattern and the fourth-layer circuit pattern; and
a fourth conductive via connecting the third-layer circuit pattern and the fourth-layer circuit pattern.

2. The PCB of claim 1, wherein the conductive via comprises a stacked via including the first and third conductive vias,
wherein the first-layer circuit pattern and the fourth-layer circuit pattern are connected to each other through the stacked via.

3. The PCB of claim 1, wherein the conductive via comprises a stacked via including the second and fourth conductive vias,
wherein the first-layer circuit pattern and the fourth-layer circuit pattern are connected to each other through the stacked via.

4. The PCB of claim 1, wherein the first insulation layer is formed of a prepreg.

5. The PCB of claim 1, wherein the second and third insulation layers are formed of a dielectric layer constituting a copper clad laminate (CCL).

6. The PCB of claim 1, wherein the first, second and third insulation layers are formed of a prepreg.

7. A PCB comprising:
a stacked structure including a first insulation layer on which a second-layer circuit pattern and a third-layer circuit pattern are formed, a second insulation layer on which a first-layer circuit pattern is formed, and a third insulation layer on which a fourth-layer circuit pattern is formed, the first insulation layer being interposed between the second and third insulation layers; and
a conductive via electrically connecting the circuit patterns,
wherein the conductive via comprises:
a first conductive via connecting the first-layer circuit pattern and the second-layer circuit pattern;
a second conductive via connecting the first-layer circuit pattern and the third-layer circuit pattern;
a third conductive via connecting the second-layer circuit pattern and the fourth-layer circuit pattern; and
a fourth conductive via connecting the third-layer circuit pattern and the fourth-layer circuit pattern.

8. The PCB of claim 7, wherein the conductive via comprises a stacked via including the first and third conductive vias,
wherein the first-layer circuit pattern and the fourth-layer circuit pattern are connected to each other through the stacked via.

9. The PCB of claim 7, wherein the conductive via comprises a stacked via including the second and fourth conductive vias,
wherein the first-layer circuit pattern and the fourth-layer circuit pattern are connected to each other through the stacked via.

10. A method of manufacturing a PCB, the method comprising:
stacking a first CCL including first and second copper foil layers and a second CCL including third and fourth copper foil layers on both sides of an adhesive layer;
forming a second-layer circuit pattern and a third-layer circuit pattern on the second and third copper foil layers not contacting the adhesive layer, respectively;
separating the first and second CCLs from the adhesive layer;
burying the second-layer circuit pattern and the third-layer circuit pattern into a prepreg by pressing the first and second CCLs with the prepreg interposed therebetween;
forming first, second, third and fourth conductive vias in the first and second CCLs and the prepreg, the first conductive via connecting a first-layer circuit pattern formed on the first copper foil layer and the second-layer circuit pattern, the second conductive via connecting the first-layer circuit pattern and the third-layer circuit pattern, the third conductive via connecting the second-layer circuit pattern and a fourth-layer circuit pattern formed on the fourth copper foil layer, and the fourth conductive via connecting the third-layer circuit pattern and the fourth-layer circuit pattern; and
forming the first-layer circuit pattern and the fourth-layer circuit pattern on the first and fourth copper foil layers, respectively.

11. A method of manufacturing a PCB, the method comprising:
attaching first and second metal foil layers on both sides of an adhesive layer;
forming a second-layer circuit pattern and a third-layer circuit pattern on the first and second metal foil layers, respectively;
separating the first and second metal foil layers from the adhesive layer;
burying the second-layer circuit pattern and the third-layer circuit pattern into a first prepreg by pressing the first and second metal foil layers with the first prepreg interposed therebetween;
stacking a second prepreg and a third metal foil layer on one side of the first prepreg, and a third prepreg and a fourth metal foil layer on the other side of the first prepreg;
forming first, second, third and fourth conductive vias in the first, second and third prepregs, the first conductive via connecting a first-layer circuit pattern formed on the third metal foil layer and the second-layer circuit pattern, the second conductive via connecting the first-layer circuit pattern and the third-layer circuit pattern, the third conductive via connecting the second-layer circuit pattern and a fourth-layer circuit pattern formed on the fourth metal foil layer, and the fourth conductive via connecting the third-layer circuit pattern and the fourth-layer circuit pattern; and
forming the first-layer circuit pattern and the fourth-layer circuit pattern on the third and fourth copper foil layers, respectively.

12. A method of manufacturing a PCB, the method comprising:
preparing a CCL including first and second copper foil layers on both sides of a dielectric layer;
forming a second-layer circuit pattern and a third-layer circuit pattern on the first and second metal foil layers, respectively;
stacking a first prepreg and a first metal foil layer on one side of the dielectric layer, and a second prepreg and a second metal foil layer on the other side of the dielectric layer;
forming first, second, third and fourth conductive vias in the first and second prepregs, the first conductive via connecting a first-layer circuit pattern formed on the first metal foil layer and the second-layer circuit pattern, the second conductive via connecting the first-layer circuit pattern and the third-layer circuit pattern, the third conductive via connecting the second-layer circuit pattern and a fourth-layer circuit pattern formed on the second metal foil layer, and the fourth conductive via connecting the third-layer circuit pattern and the fourth-layer circuit pattern; and forming the first-layer circuit pattern and the fourth-layer circuit pattern on the first and second metal foil layers, respectively.
